(19) United States
(12) Patent Application Publication
(10) Pub. No.: US 2025/0318133 A1
(43) Pub. Date: Oct. 9, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Hui Woo PARK, Gyeonggi-do (KR); Eun Seok CHOI, Gyeonggi-do (KR)

(21) Appl. No.: 18/780,475

(22) Filed: Jul. 23, 2024

(30) Foreign Application Priority Data
Apr. 5, 2024 (KR) 10-2024-0046632

(51) Int. Cl. H10B 43/40; H10B 41/27; H10B 41/40; H10B 43/27

(52) U.S. Cl. CPC H10B 43/40; H10B 41/27; H10B 41/40; H10B 43/27

(57) ABSTRACT

A manufacturing method of a semiconductor device may include forming a first stack on a first substrate, the first stack including a first surface in contact with the first substrate and a second surface located on an opposite side to the first surface; forming a tapered first opening in the first stack, the first opening extending from the second surface to the first surface; bonding the second surface of the first stack and a second substrate to each other so that the first opening is inverted; removing the first substrate so that the first surface of the first stack is exposed; forming a less tapered first opening by increasing a width of the first opening at the first surface; forming a second stack on the first surface of the first stack; and forming a second opening in the second stack, the second opening being connected to the first opening.

### CROSS-REFERENCE TO RELATED APPLICATION

This application claims priority under 35 U.S.C. § 119 to Korean Patent Application No. 10-2024-0046632 filed on Apr. 5, 2024, which is incorporated herein by reference in its entirety.

### BACKGROUND

### 1. Technical Field

Embodiments of the present disclosure relate generally to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment of the present disclosure, a manufacturing method of a semiconductor device may include forming a first stack on a first substrate, the first stack including a first surface in contact with the first substrate and a second surface located on an opposite side to the first surface; forming a tapered first opening in the first stack, the first opening extending from the second surface to the first surface; bonding the second surface of the first stack and a second substrate to each other so that the first opening is inverted; removing the first substrate so that the first surface of the first stack is exposed; forming a less tapered first opening by increasing a width of the first opening at the first surface; forming a second stack on the first surface of the first stack; and forming a second opening in the second stack, the second opening being connected to the first opening.

In an embodiment of the present disclosure, a manufacturing method of a semiconductor device may include forming a first stack on a first substrate, the first stack including a first surface in contact with the first substrate and a second surface located on an opposite side to the first surface; forming a first opening in the first stack, the first opening extending from the second surface to the first surface and being tapered; forming a second stack on the first stack, the second stack including a third surface in contact with the second surface and a fourth surface located on an opposite side to the third surface; forming a second opening in the second stack, the second opening being connected to the first opening, extending from the fourth surface to the third surface, and being tapered; removing the first substrate so that the first surface is exposed; and expanding the first opening and the second opening through the first surface.

In an embodiment of the present disclosure, a semiconductor device may include a peripheral circuit; a first gate structure located on the peripheral circuit and including first conductive layers and first insulating layers that are alternately stacked; a second gate structure located on the first gate structure and including second conductive layers and second insulating layers that are alternately stacked; a source structure located on the second gate structure; a bonding structure located between the peripheral circuit and the first gate structure and electrically connecting the peripheral circuit and the first gate structure to each other; and a channel structure including a first portion extending through the first gate structure and a second portion extending through the second gate structure, wherein a width difference between an uppermost surface and a lowermost surface of the first portion may be greater than a width difference between an uppermost surface and a lowermost surface of the second portion.

### BRIEF DESCRIPTION OF THE DRAWINGS

FIGS. 1A and 1B are diagrams illustrating the structure of a semiconductor device in accordance with an embodiment of the present disclosure.

FIGS. 2A to 2C are diagrams illustrating the structure of a semiconductor device in accordance with an embodiment of the present disclosure.

FIGS. 3A to 3I are diagrams for describing a manufacturing method of a semiconductor device in accordance with an embodiment of the present disclosure.

FIGS. 4A to 4D are diagrams for describing a modified example of a manufacturing method of a semiconductor device in accordance with an embodiment of the present disclosure.

FIGS. 5A to 5E are diagrams for describing a modified example of a manufacturing method of a semiconductor device in accordance with an embodiment of the present disclosure.

FIGS. 6A to 6C are diagrams for describing a modified example of a manufacturing method of a semiconductor device in accordance with an embodiment of the present disclosure.

FIGS. 7A to 7D are diagrams for describing a manufacturing method of a semiconductor device in accordance with an embodiment of the present disclosure.

FIG. 8 is a configuration diagram of a semiconductor device according to an embodiment of the present disclosure.

FIG. 9 is a configuration diagram of a semiconductor device according to an embodiment of the present disclosure.

### DETAILED DESCRIPTION

Various embodiments of the present disclosure are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical concept of the present disclosure will be described with reference to the accompanying drawings.

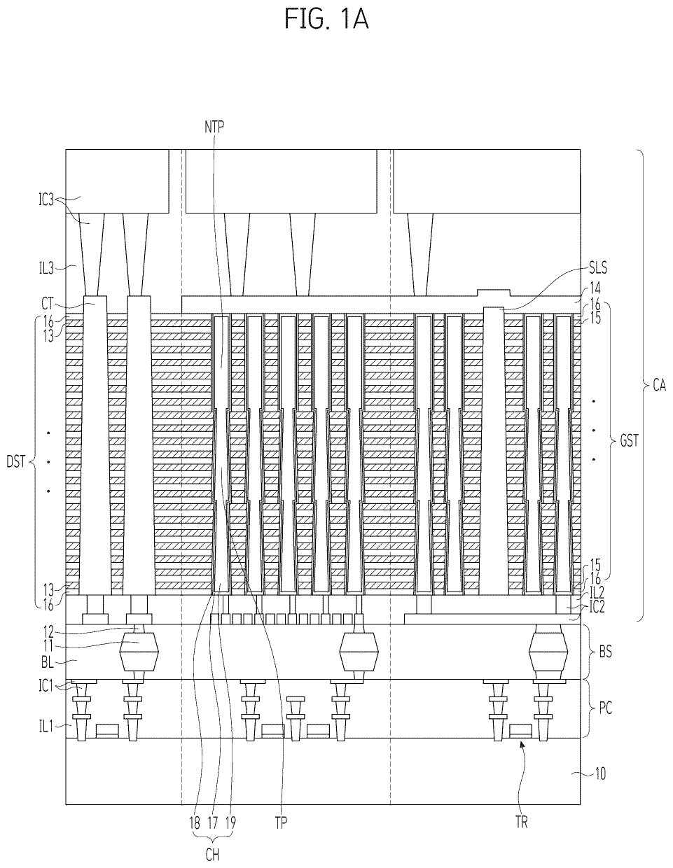

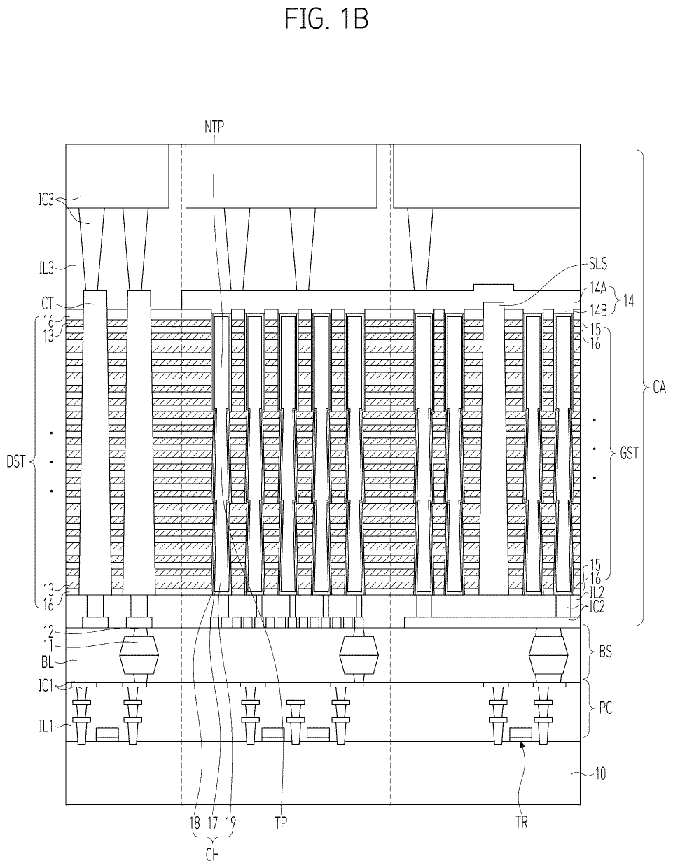

FIGS. 1A and 1B are diagrams illustrating the structure of a semiconductor device in accordance with an embodiment of the present disclosure.

Referring to FIGS. 1A and 1B, the semiconductor device may include a peripheral circuit PC, a memory cell array CA, and a bonding structure BS over a substrate 10. The bonding structure BS may be disposed between the peripheral circuit PC and the memory cell array CA.

The memory cell array CA may include a gate structure GST, a channel structure CH passing through the gate structure GST, and a source structure 14 disposed over the gate structure GST. The memory cell array CA may include at least one dummy stack DST positioned adjacent to the gate stack GST, a second interconnection structure IC2, a third interconnection structure IC3, a second interlayer insulating layer IL2, a third interlayer insulating layer IL3, a slit structure SLS passing through the gate stack GST, and at least one contact plug CT passing through the dummy stack DST.

The gate structure GST may include conductive layers 15 and insulating layers 16 that are alternately stacked. The conductive layers 15 may be gate lines such as word lines, drain select lines, or source select lines. The conductive layers 15 may each include a conductive material such as, for example, polysilicon, tungsten, or molybdenum. The insulating layers 16 are used to insulate the stacked gate lines from each other, and may each include an insulating material such as, for example, an oxide, a nitride, an air gap, or the like.

A plurality of channel structures CH may extend through the gate structure GST, each including a channel layer 17, a memory layer 18 surrounding the channel layer 17, and an insulating core 19 disposed inside the channel layer 17. The memory layer 18 may include, for example, a tunneling layer, a data storage layer, and a blocking layer. Here, the data storage layer may include polysilicon, a floating gate, nitride, a charge trap material, a variable resistance material, or the like. The channel structures CH may each include a tapered portion TP and a less tapered or non-tapered portion NTP. In the embodiment of FIG. 1A and FIG. 1B, the channel structures CH may each include two lower tapered portions and one upper non-tapered portion.

The slit structure SLS passing through the gate structure GST may be a structure formed in a slit, and may be disposed between the channel structures CH. For example, in an embodiment, the slit may be employed as a cut region (i.e., before filled with the slit structure SLS) as a passage for replacing sacrificial layers 13 with the conductive layers 15 in a manufacturing process. The slit structure SLS may be filled to include a semiconductor material, an insulating material, a conductive material, or the like.

The source structure 14 may be disposed on the gate structure GST. The channel structure CH may extend through the gate structure GST, and may be connected to the source structure 14. The slit structure SLS may extend into the source structure 14 through the gate structure GST. Referring to FIG. 1A, an uppermost surface of the channel structure CH and an uppermost surface of the gate structure GST may be disposed on the same plane. The uppermost surface of the channel structure CH may be in contact with the source structure 14. A lowermost surface of the source structure 14 may be flat or substantially flat. Moreover, the channel structure CH as shown in the embodiment of FIGS. 1A and 1B may not protrude into the source structure 14. Referring to FIG. 1B, the source structure 14 may include a plate portion 14A located on the gate structure GST and a protrusion portion 14B protruding from the bottom surface of the plate portion 14A. The source structure 14 includes protrusion portion 14B which may protrude into the gate structure GST, and may be disposed to correspond to the channel structure CH. The uppermost surface of the channel structure CH may be disposed at a lower level than the uppermost surface of the gate structure GST, and the uppermost surface of the channel structure CH may be in contact with the protrusion portion 14B. As an example, the channel layer 17 of the channel structure CH may be in contact with the protrusion portion 14B. The protrusion portion 14B may include a plurality of protrusions spaced apart from each other at a regular interval, each protrusion being positioned, and sized to come into direct contact with a top surface of the channel layer 17 of corresponding one channel structure. Hence, the plurality of protrusions may be equal in number with the channel structures CH, having a 1-1 correspondence with the channel structures CH.

The dummy stack DST may include sacrificial layers 13 and insulating layers 16 that are alternately stacked. The sacrificial layers 13 may be layers remaining without being replaced with the conductive layers 15 in the manufacturing process. The sacrificial layers 13 may each include a material having a high etching selectivity with respect to the insulating layers 16. As an example, the sacrificial layers 13 may each include nitride, and the insulating layers 16 may each include oxide. The contact plug CT may extend through the dummy stack DST.

The second interconnection structure IC2 may be disposed below the gate structure GST and the dummy stack DST. The second interconnection structure IC2 may include at least one via extending parallel to the stacking direction (e.g., a vertical direction), at least one wiring line, extending parallel to the top surface of the substrate 10 (e.g., a horizontal direction) and the like, and may be disposed in the second interlayer insulating layer IL2. The second interconnection structure IC2 may be connected to the channel structure CH, the contact plug CT, and the like. The third interconnection structure IC3 may be disposed above the gate structure GST and the dummy stack DST. The third interconnection structure IC3 may include at least one via extending parallel to the stacking direction (e.g., a vertical direction), at least one wiring line, extending parallel to the top surface of the substrate 10 (e.g., a horizontal direction) and the like, and may be disposed in the third interlayer insulating layer IL3. The third interconnection structure IC3 may be connected to the source structure 14, the contact plug CT, and the like.

The peripheral circuit PC may be any configuration suitable for driving the memory cell array CA. In an embodiment, the peripheral circuit may include at least one of a page buffer, a row decoder, a logic circuit, and the like. The peripheral circuit PC may include a first interlayer insulating layer IL1 formed on a substrate 10. The peripheral circuit may further include at least one transistor TR and at least one first interconnection structure IC1 inside the first interlayer insulating layer IL1. The transistor TR may be disposed on the substrate 10. The first interconnection structure IC1 may be connected to the transistor TR, and may connect the transistor to at least one of a bonding pad 11 or bonding via 12 positioned inside the bonding structure BS.

The bonding structure BS may be disposed between the gate structure GST and the peripheral circuit PC, and may be disposed between the first interlayer insulating layer IL1 and the second interlayer insulating layer IL2. The bonding structure BS may include a bonding layer BL, and at least one bonding pad 11, and at least one bonding via 12 positioned inside the bonding layer BS. The peripheral circuit PC and the memory cell array CA may be physically bonded to each other by the bonding layer BL. The bonding layer BL may include SiCN, tetraethyl orthosilicate (TEOS), or the like. The peripheral circuit PC and the memory cell array CA may be electrically connected to each other through the bonding pads 11 and the bonding vias 12. The bonding pads 11 and the bonding vias 12 may be electrically connected to the first and second interconnection structures IC1 IC2.

According to the structure described above, the channel structure CH may have a different shape (e.g., cross-section size) depending on a level thereof. In the illustrated example, a lower portion of the channel structure CH may have a tapered shape, and an upper portion of the channel structure CH may have a less tapered shape or a non-tapered shape. Accordingly, a width difference depending on the level of the channel structure CH may be reduced. Because the less tapered upper portion of the channel structure CH is connected to the source structure 14, a contact area between the channel structure CH and the source structure 14 may be secured, and deterioration of cell characteristics due to a decrease in contact area may be reduced. The lowermost surface of the source structure 14 may be flat or substantially flat or include the protrusion portion 14B.

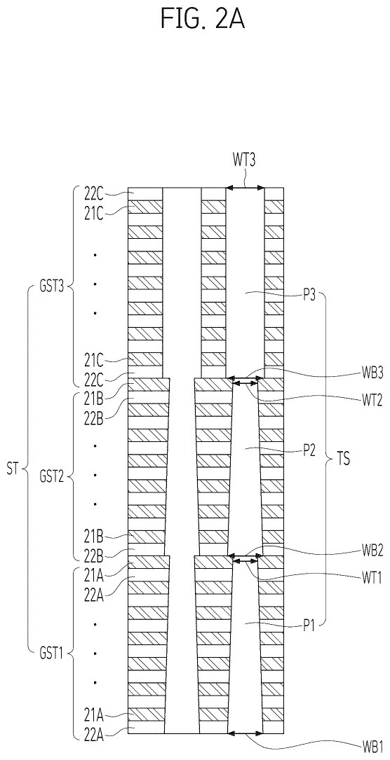

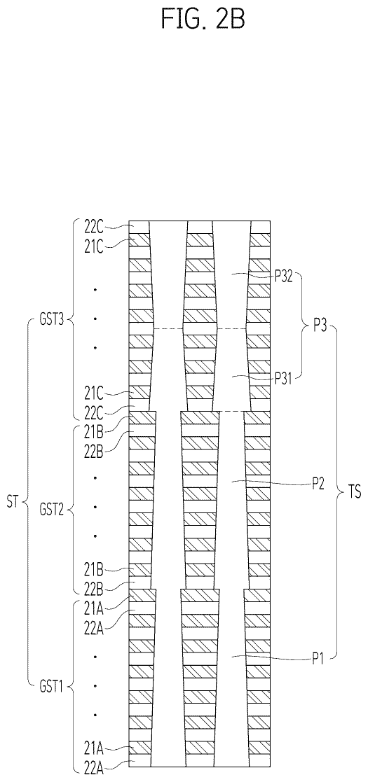

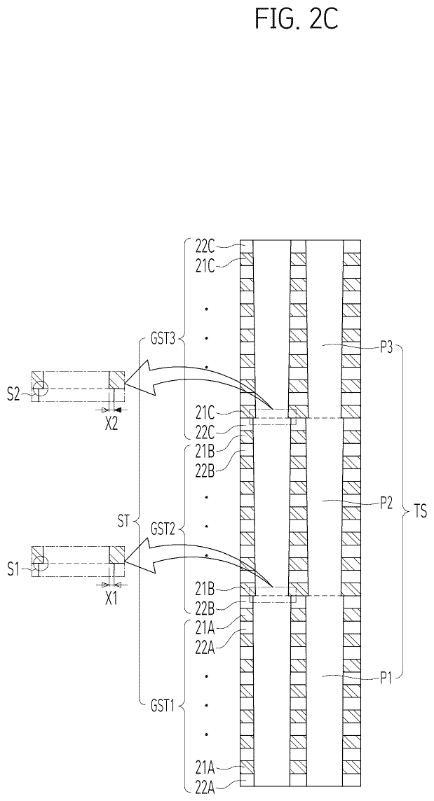

FIGS. 2A to 2C are diagrams illustrating the structure of a semiconductor device in accordance with an embodiment of the present disclosure.

Referring to FIGS. 2A to 2C, the semiconductor device may include a stack ST and a through structure TS extending through the stack ST. For example, the stack ST may be a gate structure or a dummy stack, and correspond to the gate structure GST and dummy stack DST of FIG. 1A and FIG. 1B, respectively. According to the example of FIG. 2A, the stack ST may include a first gate structure GST1, a second gate structure GST2 disposed on the first gate structure GST1, and a third gate structure GST3 disposed on the second gate structure GST2. The first gate structure GST1 may include first conductive layers 21A and first insulating layers 22A that are alternately stacked. The lowermost layer of the first gate structure GST1 may be a first insulating layer 22A. The uppermost layer of the first gate structure GST1 may be a first conductive layer 21A. The second gate structure GST2 may include second conductive layers 21B and second insulating layers 22B that are alternately stacked. The lowermost layer of the second gate structure GST2 may be a second insulating layer 22B. The uppermost layer of the second gate structure GST2 may be a second conductive layer 21B. The third gate structure GST3 may include third conductive layers 21C and third insulating layers 22C that are alternately stacked. The lowermost layer of the third gate structure GST3 may be a third insulating layer 22C. The uppermost layer of the thirds gate structure GST3 may be a third conductive layer 21C. When the stack ST is the dummy stack, the stack ST may include first to third sacrificial layers instead of the first to third conductive layers 21A to 21C.

The through structure TS may be a channel structure, a slit structure, or a contact plug. The through structure TS may include a first portion P1 extending through the first gate structure GST1, a second portion P2 extending through the second gate structure GST2, and a third portion P3 extending through the third gate structure GST3. The first, second, and third portions may be aligned in the vertical direction in a continuous manner with the second portion positioned over the first portion, and the third portion positioned over the second portion. The first, second and third portions may share a common central, longitudinal axis of symmetry extending in a direction parallel to the stacking direction.

Referring to FIG. 2A, the first portion P1 and the second portion P2 may each have an inverted tapered shape. A width WB1 of a lowermost surface of the first portion P1 may be greater than a width WT1 of an uppermost surface of the first portion P1, and a width WB2 of a lowermost surface of the second portion P2 may be greater than a width WT2 of an uppermost surface of the second portion P2. The uppermost surface of the first portion P1 and the lowermost surface of the second portion P2 may be in contact with each other, and at a contact surface, the width WB2 of the second portion P2 may be greater than the width WT1 of the first portion P1.

The third portion P3 may have a less tapered shape than the first portion P1. A width difference (WB1-WT1) between the lowermost surface and the uppermost surface of the first portion P1 may be greater than a width difference (WB3-WT3) between a lowermost surface and an uppermost surface of the third portion P3. The third portion P3 may have a less tapered shape than the second portion P2. A width difference (WB2-WT2) between the lowermost surface and the uppermost surface of the second portion P2 may be greater than the width difference (WB3-WT3) between the lowermost surface and the uppermost surface of the third portion P3. As an example, the third portion P3 may have higher width uniformity than the first portion P1 and the second portion P2.

Referring to FIG. 2B, the third portion P3 may include a lower portion P31 having an inverted tapered shape and an upper portion P32 having a tapered shape. The third portion P3 may have a minimum width at a portion where the upper portion P32 and the lower portion P31 are connected to each other. The third portion P3 may have a less tapered shape than the first portion P1 and the second portion P2.

Referring to FIG. 2C, the first, second, and third portions P1, P2, and P3 may each have a tapered shape. A first step S1 may exist at a connection portion between the first portion P1 and the second portion P2. A second step S2 may exist at a connection portion between the second portion P2 and the third portion P3. A width difference X1 between the first portion P1 and the second portion P2 at the first step S1 may be substantially the same as or different from a width difference X2 between the second portion P2 and the third portion P3 at the second step S2. In the illustrated embodiment of FIG. 2C, a width difference X1 between the first portion P1 and the second portion P2 at the first step S1 may be substantially the same as a width difference X2 between the second portion P2 and the third portion P3 at the second step S2. As another example (not shown), X1 may be smaller than X2.

According to the structure described above, the through structure TS may have different shapes (e.g., cross-sectional shape) depending on a level thereof. Also, the amount of tapering (also referred to as a tapered degree) of the first, second, and third portions P1, P2, and P3 may differ by design. In an embodiment, the width difference depending on the level of the through structure TS may be reduced, and the through structure TS may have a less tapered shape.

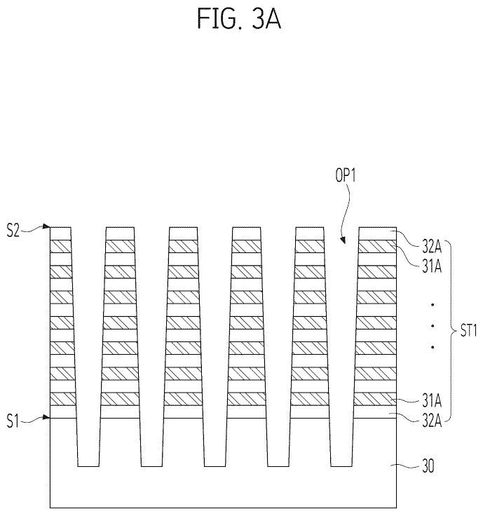

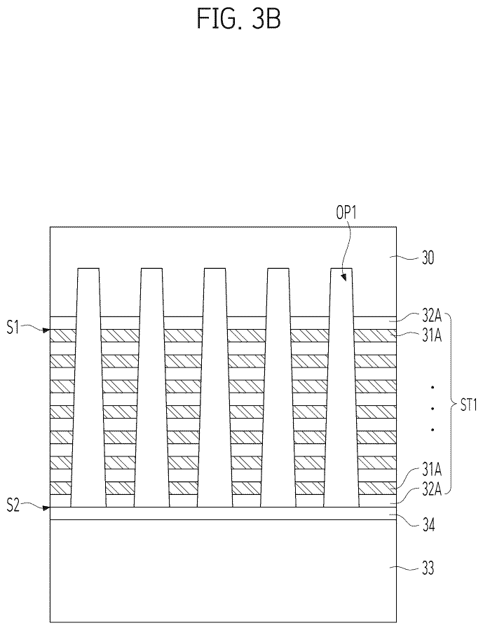

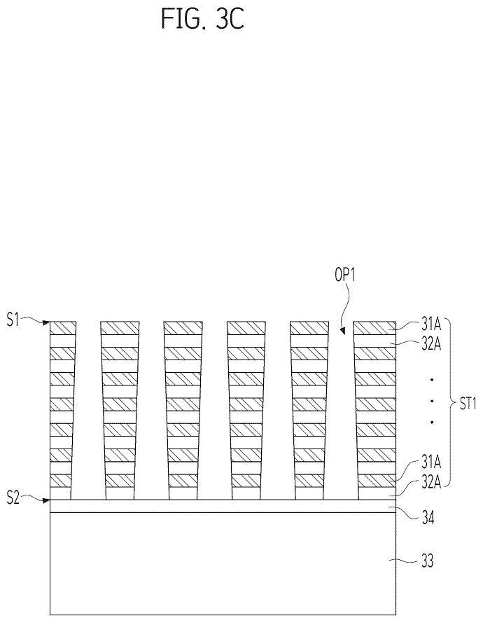

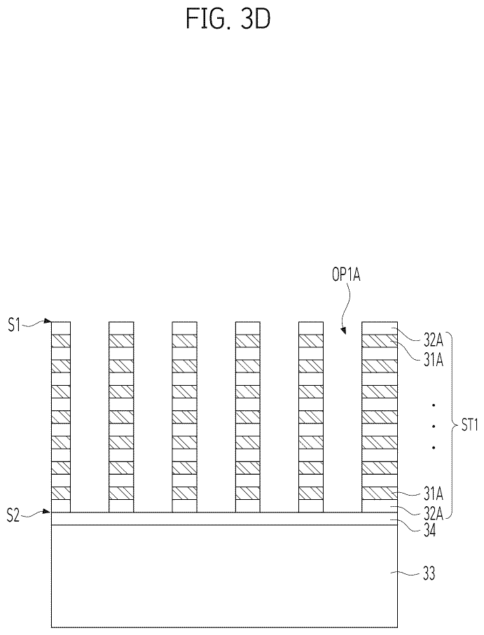

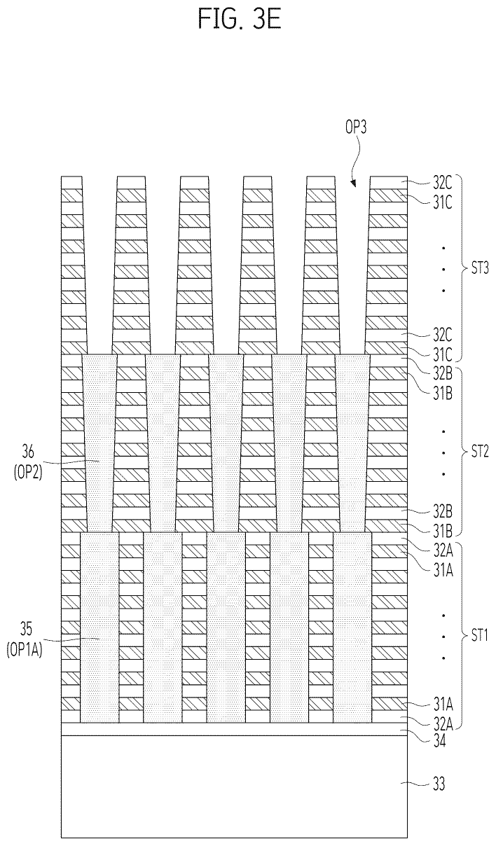

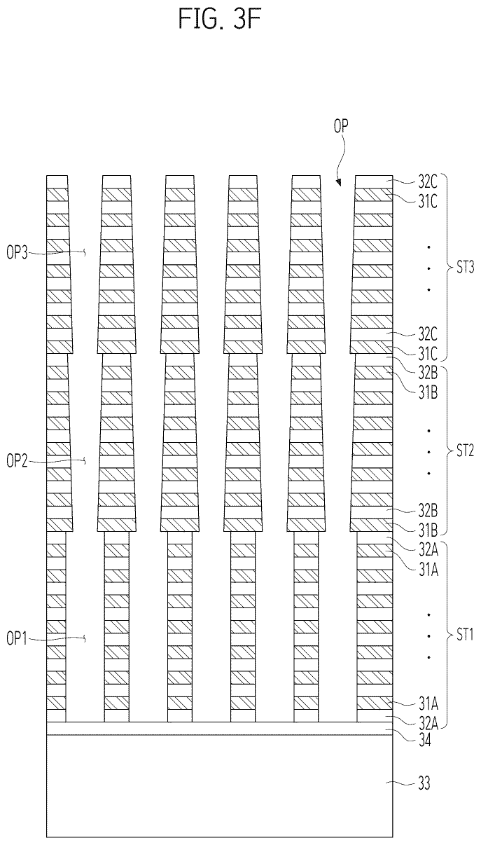

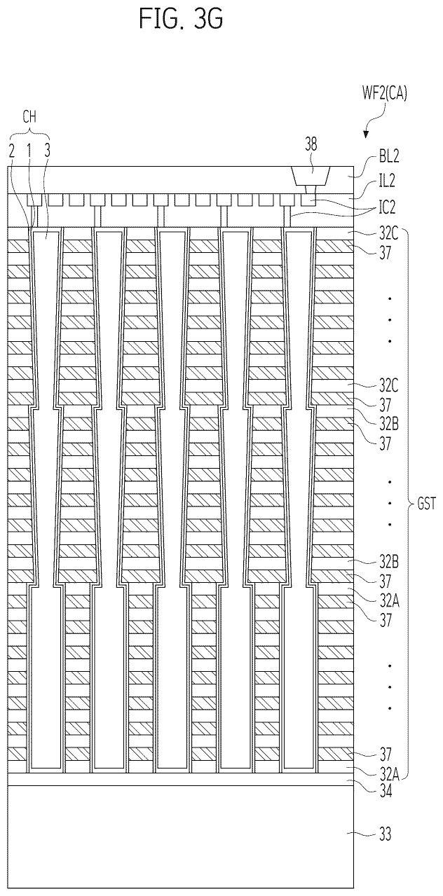

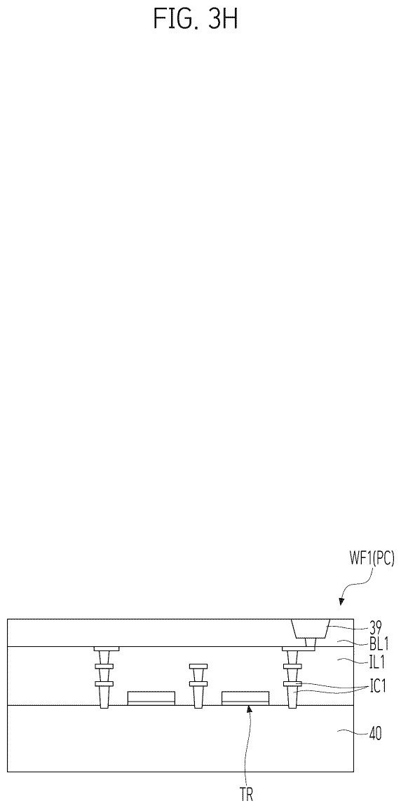

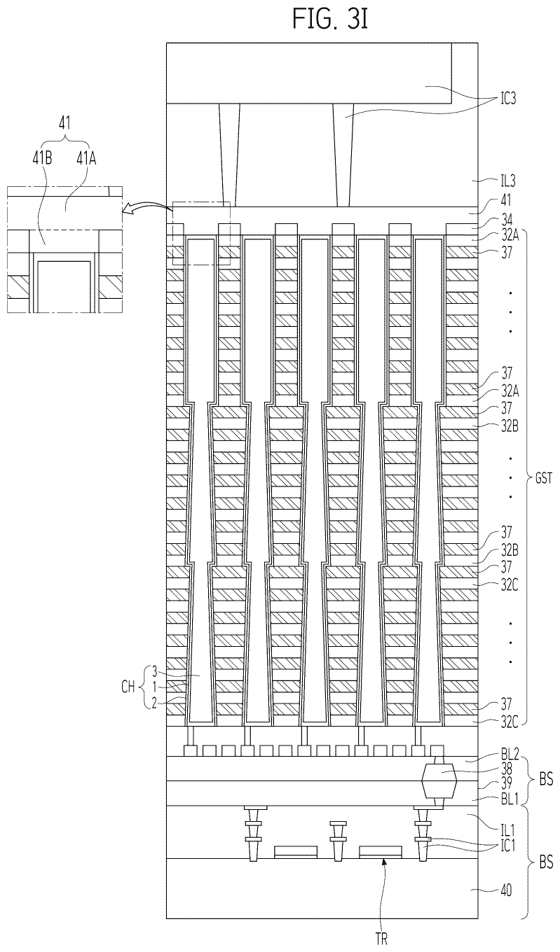

FIGS. 3A to 3I are diagrams for describing a manufacturing method of a semiconductor device in accordance with an embodiment of the present disclosure. Hereinafter, content overlapping with previously described content may be omitted.

Referring to FIG. 3A, a first stack ST1 may be formed including first and second opposite surfaces S1 and S2. The first surface S1 may be in contact with a first substrate 30. The second surface S2 may be located on an opposite side to the first surface S1 of the first stack ST1. The first stack ST1 may include first and second material layers 31A and 32A that are alternately stacked. For example, the first material layers 31A may each include a material having a high etching selectivity with respect to the second material layers 32A. The first material layers 31A may be used to form gate lines. As an example, the first material layers 31A may each include a sacrificial material such as nitride or a conductive material such as, for example, polysilicon or metal. The second material layers 32A may insulate the stacked gate lines from each other, and may each include an insulating material such as, for example, an oxide, a nitride, an air gap, or the like.

Subsequently, a tapered first opening OP1 may be formed in the first stack ST1. As illustrated in FIG. 3A a plurality of spaced apart tapered openings OP1 may be formed. Each first opening OP1 may extend from the second surface S2 to the first surface S1 and further extend into the first substrate 30. Each first opening OP1 may have a tapered shape of which a width of a lower portion is smaller than that of an upper portion. The width of the first openings OP1 may be decreasing from a maximum value at an uppermost surface thereof to a minimum value at a lowermost surface thereof.

Referring to FIG. 3B, the first stack ST1 and a second substrate 33 may be bonded to each other. More specifically, the second surface S2 of the first stack ST1 may be bonded to the second substrate 33 so that the upper portion and the lower portion of the first opening OP1 are inverted. The second substrate 33 and the second surface S2 may be bonded to each other via a bonding layer 34. For example, the bonding layer 34 may be formed on the second substrate 33, and also on the second surface S2 and then the second substrate 33 and the second surface of the first stack may be brought against each other to allow the bonding layers 34 to be bonded to each other. In this case, the second surface S2 and the bonding layer 34 may be bonded to each other in a state where the first openings OP1 remain opened. The bonding layer 34 may include any suitable material, and may, for example, include SiCN, TEOS, or the like.

Referring now to FIG. 3C, the first substrate 30 may be removed to expose the first surface S1 of the first stack ST1. The first substrate 30 may be removed through a wet cleaning process. As another example, the first substrate 30 may be removed through a planarization process. The first substrate 30 and/or the second substrate 33 may be carrier wafers used for transfer.

The first openings OP1 may be opened through the first surface S1. Because the first stack ST1 is upside down and bonded to the second substrate 33, the first openings OP1 may have an inverted tapered shape, and may have a greater width at lower portions thereof than at the upper portions thereof. Positioning the first openings OP1 in an upside down orientation, allows increasing the width of the lower portion of the first openings OP1.

Referring to FIG. 3D, less tapered first openings OP1A may be formed by increasing a width of the first openings OP1 at the first surface S1. As an example, the width of the upper portion of the first openings OP1 may be increased by etching the first stack ST1 using a top corner rounding method. Through this, the width of the upper portion of the first openings OP1 may be increased, and the less tapered first openings OP1A may be formed. The first openings OP1A may have higher width uniformity than the first openings OP1.

Referring to FIG. 3E, a first sacrificial layer 35 may be formed inside each of the first openings OP1A. The first sacrificial layer 35 may include a material having a high etching selectivity with respect to the first material layers 31A and the second material layers 32A. As an example, the first sacrificial layer 35 may include tungsten.

Subsequently, a second stack ST2 may be formed on the first surface S1 of the first stack ST1, for example, by using a deposition process. The second stack ST2 may include third and fourth material layers 31B and 32B that are alternately stacked. Here, the third material layers 31B may each include a material having a high etching selectivity with respect to the fourth material layers 32B. The third material layers 31B may be used to form gate lines. As an example, the third material layers 31B may each include a sacrificial material such as nitride or a conductive material such as polysilicon or metal. The fourth material layers 32B may insulate the stacked gate lines from each other, and may each include oxide, nitride, air gap, or the like.

Subsequently, second openings OP2 may be formed in the second stack ST2 to connect to corresponding first openings OP1A. The second openings OP2 may each have a tapered shape. The second openings OP2 may have a smaller width at a lower portion thereof than at an upper portion thereof.

Subsequently, a second sacrificial layer 36 may be formed in the second openings OP2. The second sacrificial layer 36 may include a material having a high etching selectivity with respect to the third material layers 31B and the fourth material layers 32B. As an example, the second sacrificial layer 36 may include tungsten.

Subsequently, a third stack ST3 may be formed on the second stack ST2 by using, for example, a deposition process. The third stack ST3 may include fifth and sixth material layers 31C and 32C that are alternately stacked. Here, the fifth material layers 31C may each include a material with a high etching selectivity with respect to the sixth material layers 32C. The fifth material layers 31C may be used to form gate lines. The fifth material layers 31C may each include a sacrificial material such as, for example, a nitride or a conductive material such as, for example, polysilicon or metal. The sixth material layers 32C are used to insulate the stacked gate lines from each other, and may each include, for example, an oxide, a nitride, an air gap, or the like.

Subsequently, third openings OP3 connected to corresponding second openings OP2 may be formed in the third stack ST3. The third openings OP3 may have a tapered shape. The third openings OP3 may have a smaller width at a lower portion thereof than at an upper portion thereof.

Referring to FIG. 3F, the first sacrificial layer 35 and the second sacrificial layer 36 may be removed through the third openings OP3 to form openings OP in which one of them a first opening OP1A, a second opening OP2, and a third opening OP3 are connected to each other. The openings OP may each extend through the first stack ST1, the second stack ST2, and the third stack ST3 and, therefore, may have a high aspect ratio.

Referring to FIG. 3G, a through structures may be formed in the openings OP. As an example, the through structures may be a channel structures CH. The channel structures CH may each include a channel layer 1, a memory layer 2 surrounding the channel layer 1, and an insulating core 3 located in the channel layer 1. Subsequently, the first material layers 31A, the third material layers 31B, and the fifth material layers 31C may be replaced with conductive layers 37. Through this, a gate structure GST including the conductive layers 37 and the insulating layers 32A, 32B, and 32C that are alternately stacked may be formed.

Subsequently, a second interconnection structure IC2 and a second interlayer insulating layer IL2 may be formed on the gate structure. The second interconnection structure IC2 may be disposed in the second interlayer insulating layer IL2, and may include a via, a wiring line, and the like. As an example, the second interconnection structure IC2 may include a bit line.

Subsequently, a second bonding pad 38 and a second bonding layer BL2 may be formed on the second interlayer insulating layer IL2. The second bonding pad 38 may be electrically connected to the second interconnection structure IC2. Through this, a second wafer WF2 including a memory cell array CA may be formed.

Referring to FIG. 3H, a first wafer WF1 including a peripheral circuit PC may be formed. The peripheral circuit PC may be formed on a third substrate 40. The peripheral circuit PC may include a page buffer, a row decoder, a logic circuit, and the like. As an example, the peripheral circuit PC may include a transistor TR.

Subsequently, a first interconnection structure IC1 and a first interlayer insulating layer IL1 may be formed. The first interconnection structure IC1 may be disposed in the first interlayer insulating layer IL1, and may be electrically connected to the peripheral circuit PC. The first interconnection structure IC1 may include a via (e.g., extending vertically), a wiring line (e.g., extending horizontally), and the like.

Subsequently, a first bonding pad 39 and a first bonding layer BL1 may be formed on the first interlayer insulating layer IL1. The first bonding pad 39 may be electrically connected to the first interconnection structure IC1. Through this, the first wafer WF1 including the peripheral circuit PC may be formed.

Referring to FIG. 3I, the first and second wafers WF1 and WF2 may be bonded to each other so that the first and second bonding layers BL1 and BL2 are bonded to each other. Through this, the first wafer WF1 including the peripheral circuit PC and the second wafer WF2 including the channel structure CH may be bonded to each other. The first bonding pad 39 and the second bonding pad 38 may be electrically connected to each other, and the peripheral circuit PC and the memory cell array CA may be electrically connected to each other.

Subsequently, the second substrate 33 may be removed, and the bonding layer 34 may be etched to expose the channel structure CH. As an example, a mask pattern may be formed on the bonding layer 34, and the bonding layer 34 may be etched using the mask pattern as an etching barrier to form an opening exposing the channel structure CH. Subsequently, the memory layer 2 may be etched to expose the channel layer 1. Alternatively, the bonding layer 34 may be planarized so the channel structure CH is exposed, and the memory layer 2 may be etched to expose the channel layer 1.

Subsequently, a source structure 41 may be formed on the gate structure GST. The source structure 41 may include a plate portion 41A and a protrusion portion 41B. The protrusion portion 41B may be formed in the opening, and may be in contact with the channel layer 1. In an embodiment, when the bonding layer 34 is planarized, the source structure 41 may include only the plate portion 41A without the protrusion portion 41B.

Subsequently, a third interconnection structure IC3 and a third interlayer insulating layer IL3 may be formed. The third interconnection structure IC3 may be disposed in the third interlayer insulating layer IL3, and may include a via, a wiring line, and the like. As an example, the third interconnection structure IC3 may be electrically connected to the source structure 41.

According to the manufacturing method described above, a width of a lower portion of the opening OP may be increased using a wafer bonding method. Accordingly, the channel structure CH may have a less tapered structure, and a contact area between the channel layer 1 and the source structure 41 may be increased. Through this, characteristics such as a cell current may be improved.

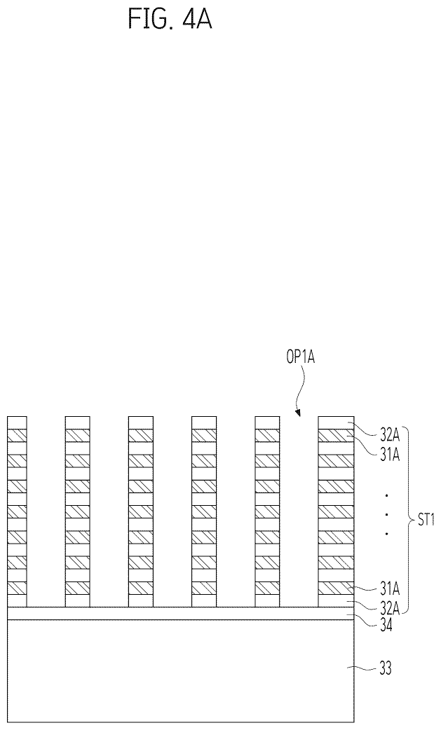

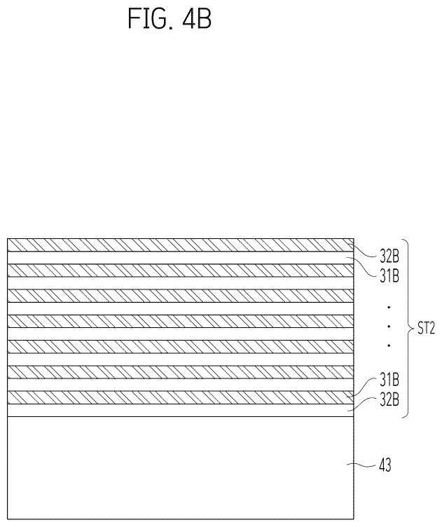

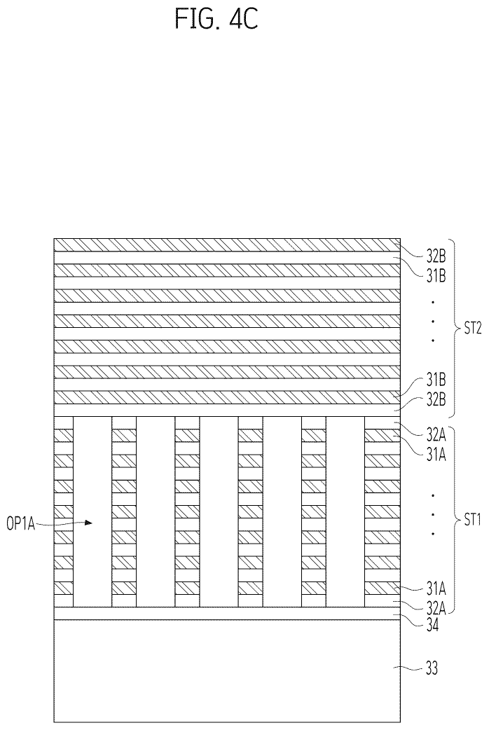

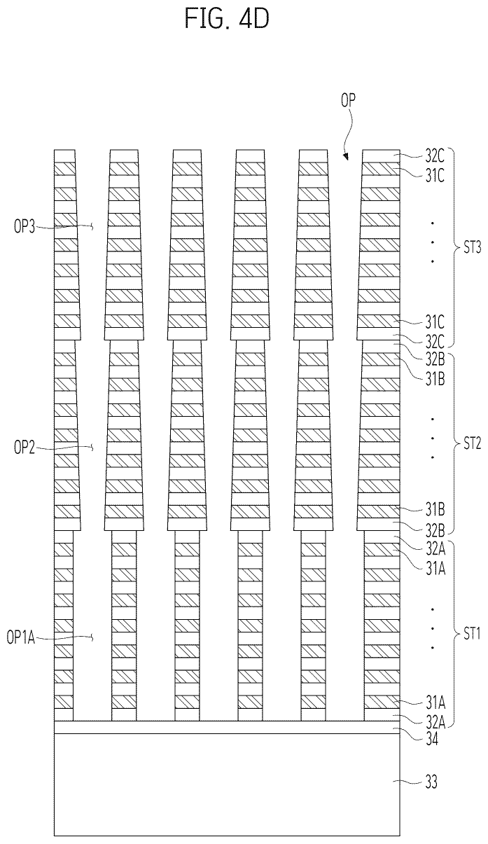

FIGS. 4A to 4D are diagrams for describing a modified example of a manufacturing method of a semiconductor device in accordance with an embodiment of the present disclosure. Hereinafter, content overlapping with the previously described content may be omitted.

FIG. 4A is a diagram corresponding to FIG. 3D described above. Referring to FIG. 4A, the first stack ST1 may be disposed on the second substrate 33, and may include first material layers 31A and second material layers 32A that are alternately stacked. Less tapered first openings OP1A may be formed in the first stack ST1.

Referring to FIG. 4B, a second stack ST2 may be formed on carrier wafer 43. The second stack ST2 may include third and fourth material layers 31B and 32B that are alternately stacked.

Referring to FIG. 4C, the first stack ST1 and the second stack ST2 may be bonded to each other in a state where the first openings OP1A are opened. As an example, the second material layer 32A and the fourth material layer 32B may be bonded to each other. In a state where a sacrificial layer is not formed in the first openings OP1A, the first stack ST1 and the second stack ST2 may be bonded to each other.

Referring to FIG. 4D, a plurality of second openings OP2 may be formed in the second stack ST2. The second openings OP2 may be connected to corresponding ones of the first openings OP1A, and may have a tapered shape.

Subsequently, a third stack ST3 may be bonded to the second stack ST2 using a carrier wafer. The second stack ST2 and the third stack ST3 may be bonded to each other in a state where the first openings OP1A and the second openings OP2 are opened. The third stack ST3 may include fifth material layers 31C and sixth material layers 32C that are alternately stacked. As an example, the fourth material layer 32B and the sixth material layer 32C may be bonded to each other. In a state where a sacrificial layer is not formed in the first openings OP1A and the second openings OP2, the second stack ST2 and the third stack ST3 may be bonded to each other.

Subsequently, third openings OP3 may be formed in the third stack ST3. The third openings OP3 may be connected to the second openings OP2, and may have a tapered shape. Through this, the first openings OP1A, the second openings OP2, and the third openings OP3 may be connected to each other, and openings OP may be formed. Subsequently, a through structure, for example, a channel structure, may be formed in each of the openings OP.

According to the manufacturing method described above, in forming the openings OP having a high aspect ratio in a divided manner plural times, the stacks may be bonded to each other using a wafer bonding method. When the wafer bonding method is used, the second stack ST2 and the third stack ST3 may be bonded to each other in the state where the first openings OP1A and the second openings OP2 are opened. Accordingly, the sacrificial layer might not be formed in the first openings OP1A and the second openings OP2, and a process of removing the sacrificial layer before forming the through structure may be omitted.

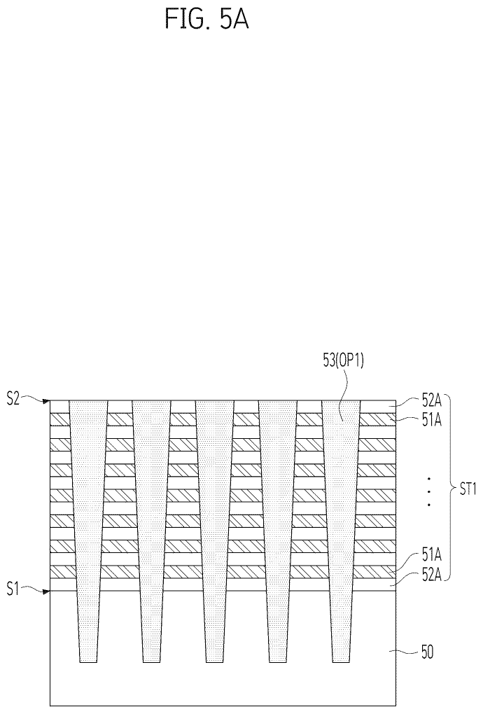

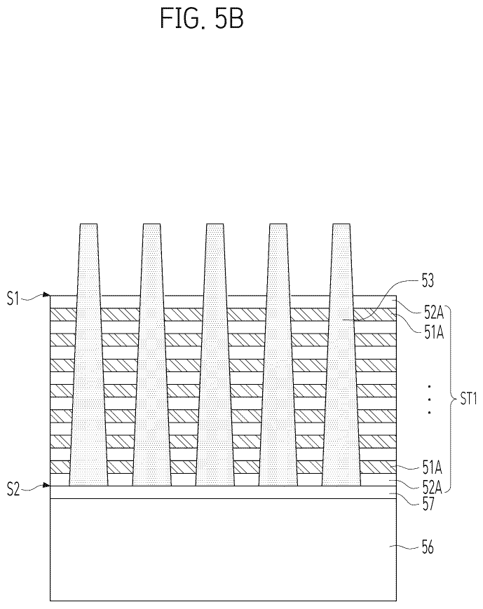

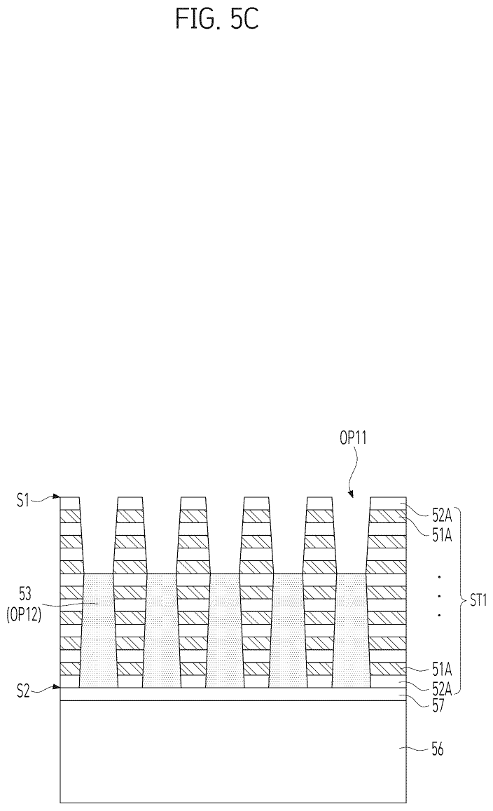

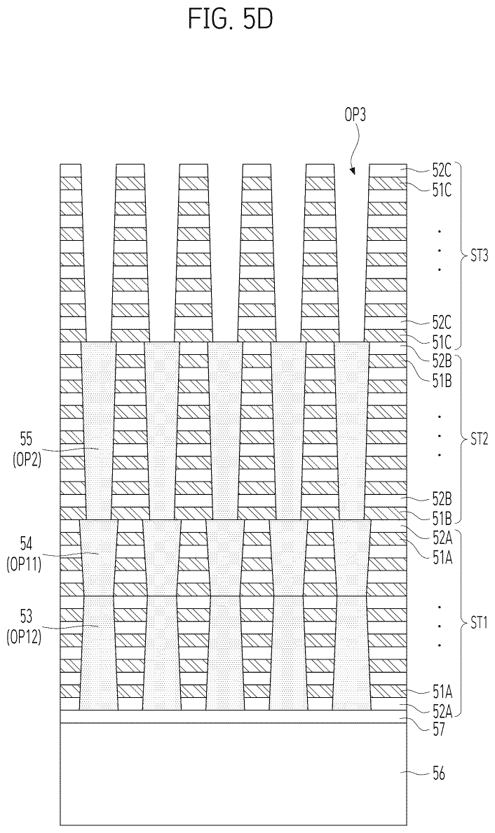

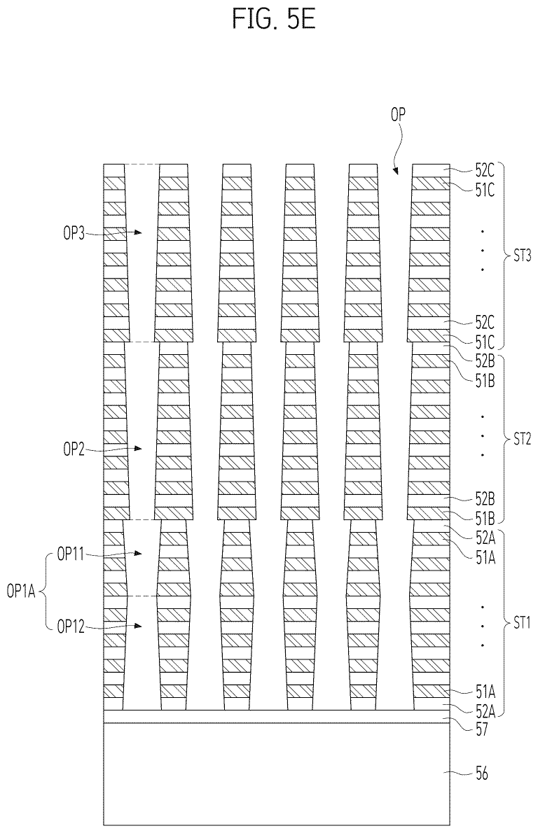

FIGS. 5A to 5E are diagrams for describing a modified example of a manufacturing method of a semiconductor device in accordance with an embodiment of the present disclosure. Hereinafter, content overlapping with previously described content may be omitted.

Referring to FIG. 5A, a first stack ST1 may be formed on a first substrate 50. The first stack ST1 may include a first surface S1 in contact with the first substrate 50 and a second surface S2 located on an opposite side to the first surface S1. The first stack ST1 may include first material layers 51A and second material layers 52A that are alternately stacked. Here, the first material layers 51A may each include a material having a high etching selectivity with respect to the second material layers 52A. The first material layers 51A may be used to form gate lines. As an example, the first material layers 51A may each include a sacrificial material such as nitride or a conductive material such as, for example, polysilicon or metal. The second material layers 52A are used to insulate the stacked gate lines from each other, and may each include oxide, nitride, air gap, or the like.

Subsequently, tapered first openings OP1 may be formed in the first stack ST1. The first openings OP1 may extend from the second surface S2 toward the first surface S1 and extend into the first substrate 50. The first openings OP1 may have a tapered shape of which a width of a lower portion is smaller than a width of an upper portion. Subsequently, a first sacrificial layer 53 may be formed inside the first openings OP1. The first sacrificial layer 53 may include a material having a high etching selectivity with respect to the first material layers 51A and the second material layers 52A. As an example, the first sacrificial layer 53 may include tungsten or polysilicon. The first sacrificial layer 53 may have a similar shape to the first openings OP1, and may have a cross section with a tapered shape of which a width of a lower portion is smaller than that of an upper portion.

Referring to FIG. 5B, the second surface S2 of the first stack ST1 and a second substrate 56 may be bonded to each other via a bonding layer 57. As an example, the bonding layer 57 may be formed on the second substrate 56, and on the second surface S2 and the bonding layer 57 may be bonded to each other. The bonding layer 57 may include SiCN, TEOS, or the like.

Subsequently, the first substrate 50 may be removed to expose the first surface S1 of the first stack ST1. The first sacrificial layer 53 may protrude from the first surface S1 of the first stack ST1. Because the first stack ST1 is upside down and bonded to the second substrate 56, the first sacrificial layer 53 may be arranged in an inverted tapered shape, and may have a greater width at the lower portion thereof than at the upper portion thereof. That is, by locating the first sacrificial layer 53 upside down, it is possible to obtain an effect of increasing the width of the lower portion of the first sacrificial layer 53.

Referring to FIG. 5C, the first sacrificial layer 53 may be partially removed through the first surface S1. Through this, a partial region of each of the tapered first openings OP1 may be reopened. An upper region OP11 having a relatively small width in the first openings OP1 may be reopened, and the first sacrificial layer 53 may remain in a lower region OP12 having a relatively great width in the first openings OP1.

Subsequently, the reopened upper region OP11 may be expanded. The first stack ST1 may be etched through the reopened upper region OP11. In this case, etching may be concentrated on a top corner of the first openings OP1, and a width of the top corner may be increased. Through this, the upper region OP11 may have a less tapered shape.

Referring to FIG. 5D, a second sacrificial layer 54 may be formed in the upper region OP11. The second sacrificial layer 54 may include a material having a high etching selectivity with respect to the first material layers 51A and the second material layers 52A. As an example, the second sacrificial layer 54 may include tungsten or polysilicon.

Subsequently, a second stack ST2 may be formed. The second stack ST2 may include third material layers 51B and fourth material layers 52B that are alternately stacked. The second stack ST2 may be formed using a stacking method or a wafer bonding method. In an embodiment, it is also possible to bond the second stack ST2 in a state where the upper regions OP11 are not filled. Subsequently, a plurality of second openings OP2 may be formed in the second stack ST2, and a third sacrificial layer 55 may be formed in each of the second openings OP2.

Subsequently, a third stack ST3 may be formed. The third stack ST3 may include fifth material layers 51C and sixth material layers 52C that are alternately stacked. The third stack ST3 may be formed using a stacking method or a wafer bonding method. In an embodiment, it is also possible to bond the third stack ST3 in a state where the second openings OP2 are not filled. Subsequently, third openings OP3 connected to corresponding ones of the second openings OP2 may be formed in the third stack ST3.

Referring to FIG. 5E, the first sacrificial layer 53, the second sacrificial layer 54, and the third sacrificial layer 55 may be removed through the third openings OP3, and openings OP in each of which a first opening OP1A, the second opening OP2, and the third opening OP3 are connected to each other may be formed. Here, FIG. 5E may correspond to FIG. 3F, and subsequent processes may be similar to those of FIGS. 3G to 3I.

According to the manufacturing method described above, by locating the first openings OP1 upside down, it is possible to increase a width of the lower portion of the openings OP. In addition, by selectively etching the first stack ST1 exposed through the upper regions OP11 having the relatively small width in the first openings OP1, it is possible to form a less tapered first openings OP1A.

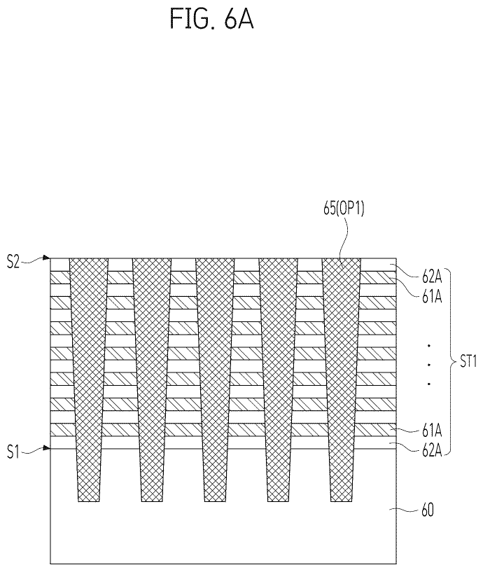

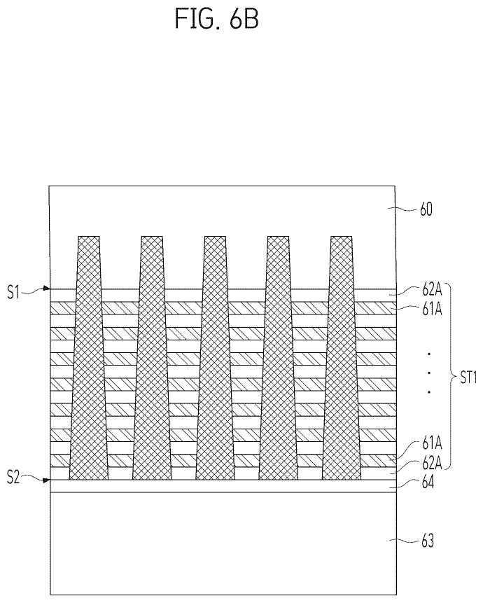

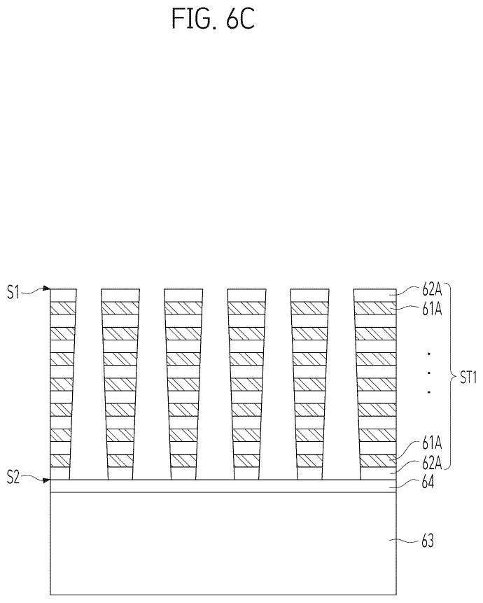

FIGS. 6A to 6C are diagrams for describing a modified example of a manufacturing method of a semiconductor device in accordance with an embodiment of the present disclosure, and may correspond to FIGS. 3A to 3C described above. Hereinafter, the content overlapping with the previously described content may be omitted.

Referring to FIG. 6A, a first stack ST1 including a first surface S1 in contact with a first substrate 60 and a second surface S2 located on an opposite side to the first surface S1 may be formed on the first substrate 60. The first stack ST1 may include first material layers 61A and second material layers 62A that are alternately stacked.

Subsequently, first openings OP1 extending into the first substrate 60 through the first stack ST1 may be formed. The first openings OP1 may have a cross section with a tapered shape of which a width of the first surface S1 is smaller than that of the second surface S2. Subsequently, sacrificial layers 65 may be formed in the first openings OP1. The sacrificial layer 65 may include a material having an etch rate similar to that of the first substrate 60. As an example, the sacrificial layer 65 may include polysilicon.

Referring to FIG. 6B, the second surface S2 of the first stack ST1 and a second substrate 63 may be bonded to each other. As an example, a bonding layer 64 may be formed on the second substrate 63, and the second surface S2 and the bonding layer 64 may be bonded to each other. In this case, the second surface S2 and the bonding layer 64 may be bonded to each other in a state where the sacrificial layers 65 are filled in the first openings OP1.

Referring to FIG. 6C, the first substrate 60 may be removed so that the first surface S1 of the first stack ST1 is exposed. The first substrate 60 may be removed through a wet cleaning process or a planarization process. When the first substrate 60 is removed, the sacrificial layers 65 may be removed together with the first substrate 60. As the sacrificial layers 65 are removed, the first openings OP1 may be reopened through the first surface S1. Subsequent processes may be similar to those of FIGS. 3D to 3I.

According to the manufacturing method described above, when the first substrate 60 is removed, the sacrificial layer 65 may be removed simultaneously with the first substrate 60. Accordingly, the second substrate 63 may be bonded in the state where the sacrificial layer 65 is filled in the first openings OP1, and a process of removing the sacrificial layer 65 may be omitted.

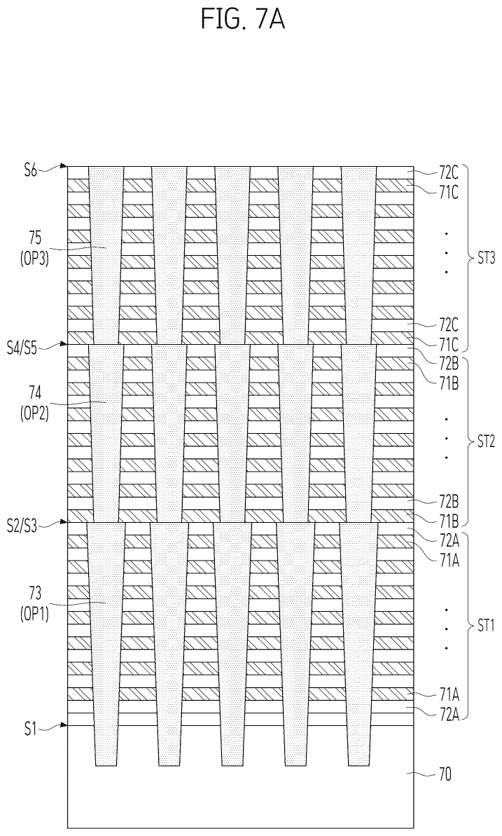

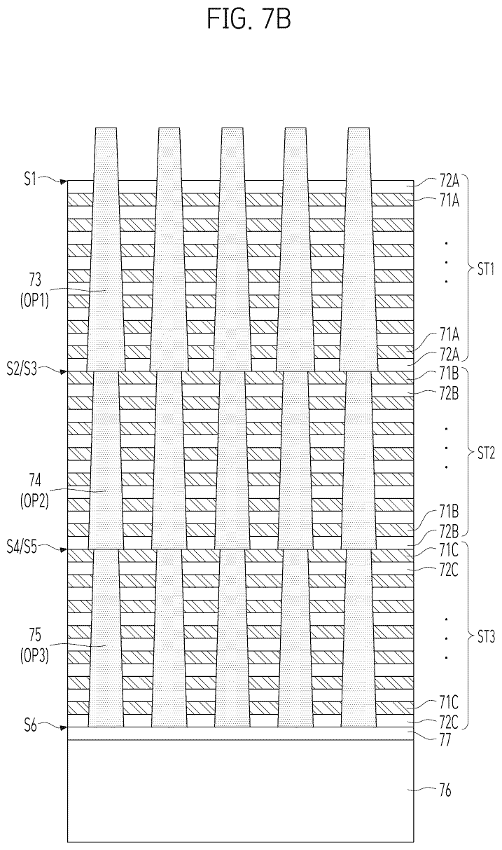

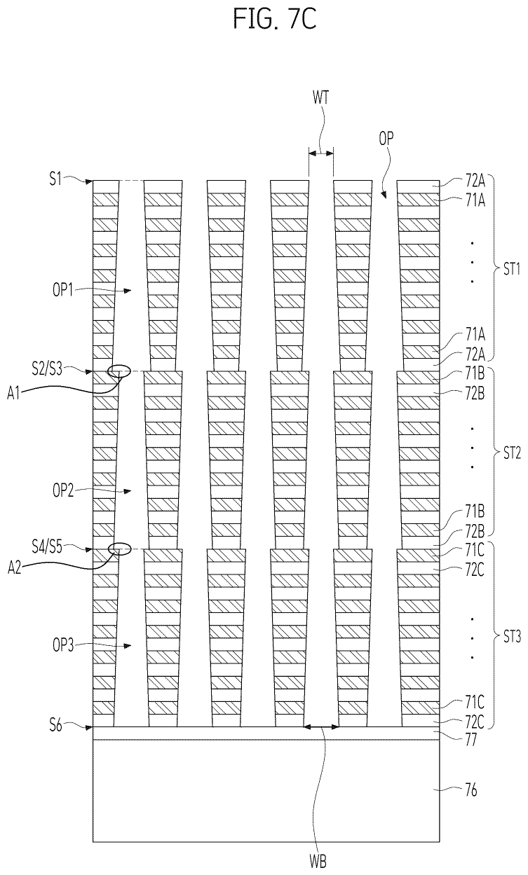

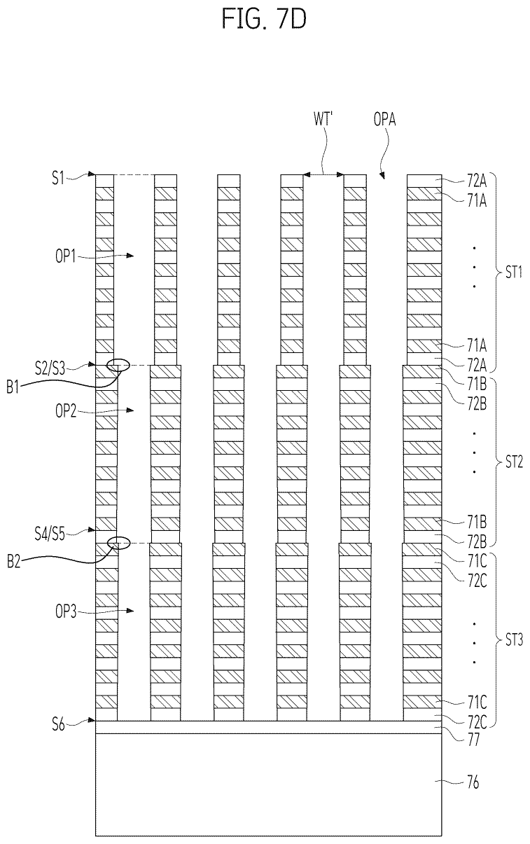

FIGS. 7A to 7D are diagrams for describing a manufacturing method of a semiconductor device in accordance with an embodiment of the present disclosure. Hereinafter, the content overlapping with the previously described content may be omitted.

Referring to FIG. 7A, a first stack ST1 including a first surface S1 in contact with a first substrate 70 and a second surface S2 located on an opposite side to the first surface S1 may be formed on the first substrate 70. The first stack ST1 may include first material layers 71A and second material layers 72A that are alternately stacked. Subsequently, first openings OP1 extending into the first substrate 70 through the first stack ST1 may be formed. The first openings OP1 may extend from the second surface S2 to the first surface S1, and may have a cross section with a tapered shape. Subsequently, a first sacrificial layer 73 may be formed in the first openings OP1.

Subsequently, a second stack ST2 including a third surface S3 in contact with the second surface S2 and a fourth surface S4 located on an opposite side to the third surface S3 may be formed on the first stack ST1. The second stack ST2 may include third material layers 71B and fourth material layers 72B that are alternately stacked. Subsequently, a plurality of second openings OP2 extending through the second stack ST2 and connected to the first openings OP1 may be formed. The second openings OP2 may extend from the fourth surface S4 to the third surface S3, and may have a cross section with a tapered shape. Subsequently, a second sacrificial layers 74 may be formed in the second openings OP2.

Subsequently, a third stack ST3 including a fifth surface S5 in contact with the fourth surface S4 and a sixth surface S6 located on an opposite side to the fifth surface S5 may be formed on the second stack ST2. The third stack ST3 may include fifth material layers 71C and sixth material layers 72C that are alternately stacked. Subsequently, third openings OP3 extending through the third stack ST3 and connected to the second openings OP2 may be formed. The third openings OP3 may extend from the sixth surface S6 to the fifth surface S5, and may have a cross section with a tapered shape. Subsequently, a third sacrificial layer 75 may be formed in the third openings OP3.

In an embodiment, the second surface S2 of the first stack ST1 and the third surface S3 of the second stack ST2 may be bonded to each other in a state where the first openings OP1 are empty. The fourth surface S4 of the second stack ST2 and the fifth surface S5 of the third stack ST3 may be bonded to each other in a state where the second openings OP2 are empty.

Referring to FIG. 7B, the third stack ST3 and a second substrate 76 may be bonded to each other. As an example, a bonding layer 77 may be formed on the second substrate 76, and the sixth surface S6 of the third stack ST3 and the bonding layer 77 may be bonded to each other. In an embodiment, the sixth surface S6 of the third stack ST3 and the second substrate 76 may be bonded to each other in a state where the third openings OP3 are empty.

Subsequently, the first substrate 70 may be removed so that the first surface S1 of the first stack ST1 is exposed. The first sacrificial layer 73 may protrude from the first surface S1 of the first stack ST1.

Referring to FIG. 7C, the third sacrificial layer 75, the second sacrificial layer 74, and the first sacrificial layer 73 may be removed through the first surface S1 of the first stack ST1. Through this, the first openings OP1, the second openings OP2, and the third openings OP3 may be opened, and openings OP having a high aspect ratio may be formed. The lowermost portion of the openings OP may have a relatively great width WB, and the uppermost portion of the openings OP may have a relatively small width WT.

Because the first to third openings OP1 to OP3 each have the tapered shape, steps A1 and A2 may exist at connection portions between the first to third openings OP1 to OP3. A first step A1 may exist at a portion where the first openings OP1 and the second openings OP2 are connected to each other, and a second step A2 may exist at a portion where the second openings OP2 and the third openings OP3 are connected to each other. A width difference at the first step A1 and a width difference at the second step A2 may be substantially the same as or similar to each other.

In an embodiment, similar to an embodiment described above with reference to FIG. 5C, it is also possible to remove some of the first sacrificial layer 73, the second sacrificial layer 74, and the third sacrificial layer 75. As an example, it is also possible to open only an upper region having a relatively small width in each of the third openings OP3 by partially removing the third sacrificial layer 75.

Referring to FIG. 7D, each of the first openings OP1, the second openings OP2, and the third openings OP3 may be expanded through the first surface S1. As an example, the first stack ST1, the second stack ST2, and the third stack ST3 exposed through the openings OP may be etched. Through this, a width of the first openings OP1 at the first surface S1 may be expanded. Etching may be concentrated on a top corner of the openings OP, and a width WT′ of the uppermost portion of the openings OP may be increased.

In addition, etching may be concentrated on steps B1 and B2, and width differences at the steps B1 and B2 may be reduced. A width difference between the first openings OP1 and the second openings OP2 at a connection portion between the first openings OP1 and the second openings OP2 may be reduced, and a width difference between the second openings OP2 and the third openings OP3 at a connection portion between the second openings OP2 and the third openings OP3 may be reduced. Through this, a less tapered openings OPA may be formed.

In this case, etching atmospheres may be different from each other depending on locations of the steps. A first step B1 located at the connection between the first openings OP1 and the second openings OP2 may be disposed above a second step B2 located at the connection between the second openings OP2 and the third openings OP3, and the first step B1 may be more exposed to the etching atmosphere than the second step B2 is. In such a case, an etching amount of the first step B1 may be greater than that of the second step B2. Accordingly, a width difference between the second openings OP2 and the third openings OP3 at the second step B2 may be greater than a width difference between the first openings OP1 and the second openings OP2 at the first step B1.

Here, FIG. 7D may correspond to FIG. 3F, and subsequent processes may be similar to those of FIGS. 3G to 3I.

According to the manufacturing method described above, the third openings OP3 having the tapered shape are inverted to form a lower portion of the openings OP. Accordingly, the width WB of the lowermost portion of the openings OP may be increased. In addition, because an etching process is performed in a state where the openings OP are opened, it is possible to not only increase the width WT of the uppermost portion of the openings OP but also reduce the width differences at the steps B1 and B2. Accordingly, the less tapered openings OPA may be formed.

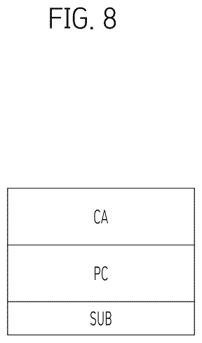

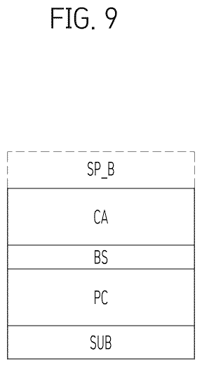

The structure and the manufacturing method according to the above-described embodiments may be applied to semiconductor devices of various structures. FIGS. 8 and 9 illustrate a schematic configuration of a semiconductor device to which the above-described embodiments are applicable.

FIG. 8 is a configuration diagram of a semiconductor device according to an embodiment of the present disclosure.

Referring to FIG. 8, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInASP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 9 is a configuration diagram of a semiconductor device according to an embodiment of the present disclosure.

Referring to FIG. 9, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

In an embodiment, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 8.

Moreover, the semiconductor device may have a structure in which the embodiments described above with reference to FIGS. 8 and 9 are combined or may have a partially modified structure. In the embodiment described with reference to FIGS. 8 and 9, positions of the memory cell array CA and the peripheral circuit PC may be changed. At least one memory cell array CA and/or at least one peripheral circuit PC may be additionally bonded to the embodiment described with reference to FIG. 8. In an embodiment, a portion of the peripheral circuitry PC may be disposed in the memory cell array CA.

Although embodiments according to the technical concept of the present disclosure have been described above with reference to the accompanying drawings, this is only for describing the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical concept of the present disclosure defined in the following claims, and it should be construed that these substitutions, modifications, changes, and combinations belong to the scope of the present disclosure. Furthermore, the embodiments may be combined to form additional embodiments.

What is claimed is:

1. A manufacturing method of a semiconductor device, the manufacturing method comprising:
forming a first stack on a first substrate, the first stack including a first surface in contact with the first substrate and a second surface located on an opposite side to the first surface;
forming a tapered first opening in the first stack, the first opening extending from the second surface to the first surface;
bonding the second surface of the first stack and a second substrate to each other so that the first opening is inverted;
removing the first substrate so that the first surface of the first stack is exposed;
forming a less tapered first opening by increasing a width of the first opening at the first surface;
forming a second stack on the first surface of the first stack; and
forming a second opening in the second stack, the second opening being connected to the first opening.

2. The manufacturing method of claim 1, wherein in the bonding of the second surface of the first stack and the second substrate to each other, the second surface and the second substrate are bonded to each other in a state where the tapered first opening is opened.

3. The manufacturing method of claim 1, wherein the forming the second stack comprises:
forming a first sacrificial layer in the less tapered first opening; and
depositing the second stack on the first surface of the first stack.

4. The manufacturing method of claim 1, wherein in the forming of the second stack, the first surface and the second stack are bonded to each other.

5. The manufacturing method of claim 4, wherein the first surface and the second stack are bonded to each other in a state where the less tapered first opening is opened.

6. The manufacturing method of claim 1, further comprising:
forming a third stack on the second stack; and
forming a third opening in the third stack, the third opening being connected to the second opening.

7. The manufacturing method of claim 1, further comprising forming a sacrificial layer in the tapered first opening.

8. The manufacturing method of claim 7, wherein the forming of the less tapered first opening comprises:
reopening a partial region of the tapered first opening by partially removing the sacrificial layer through the first surface; and
expanding the reopened region.

9. The manufacturing method of claim 7, wherein the sacrificial layer is removed when the first substrate is removed.

10. The manufacturing method of claim 1, further comprising forming a channel structure in the less tapered first opening and the second opening.

11. The manufacturing method of claim 10, further comprising:
bonding a first wafer and a second wafer to each other, the first wafer including a peripheral circuit, and the second wafer including the channel structure;
removing the second substrate so that the channel structure is exposed; and
forming a source structure connected to the channel structure.

12. A manufacturing method of a semiconductor device, the manufacturing method comprising:
forming a first stack on a first substrate, the first stack including a first surface in contact with the first substrate and a second surface located on an opposite side to the first surface;
forming a first opening in the first stack, the first opening extending from the second surface to the first surface and being tapered;
forming a second stack on the first stack, the second stack including a third surface in contact with the second surface and a fourth surface located on an opposite side to the third surface;
forming a second opening in the second stack, the second opening being connected to the first opening, extending from the fourth surface to the third surface, and being tapered;
removing the first substrate so that the first surface is exposed; and
expanding the first opening and the second opening through the first surface.

13. The manufacturing method of claim 12, wherein in the expanding of the first opening and the second opening, a width of the first opening at the first surface is expanded.

14. The manufacturing method of claim 12, wherein in the expanding of the first opening and the second opening, a width difference between the first opening and the second opening at a connection portion between the first opening and the second opening is reduced.

15. The manufacturing method of claim 12, wherein in the forming of the second stack, the second surface of the first stack and the third surface of the second stack are bonded to each other.

16. The manufacturing method of claim 12, wherein the forming of the second stack comprises:
forming a first sacrificial layer in the first opening; and
depositing the second stack on the second surface of the first stack.

17. The manufacturing method of claim 16, further comprising removing the first sacrificial layer after removing the first substrate.

18. The manufacturing method of claim 12, further comprising:
bonding the fourth surface of the second stack and a second substrate to each other; and
forming a channel structure in the first opening and the second opening.

19. The manufacturing method of claim 18, further comprising:
bonding a first wafer and a second wafer to each other, the first wafer including a peripheral circuit, and the second wafer including the channel structure;
removing the second substrate so that the channel structure is exposed; and
forming a source structure connected to the channel structure.

20. The manufacturing method of claim 12, further comprising:
forming a third stack on the second stack, the third stack including a fifth surface in contact with the fourth surface and a sixth surface located on an opposite side to the fifth surface; and
forming a third opening in the third stack, the third opening being connected to the second opening, extending from the sixth surface to the fifth surface, and being tapered.

21. A semiconductor device comprising:
a peripheral circuit;
a first gate structure located on the peripheral circuit and including first conductive layers and first insulating layers that are alternately stacked;
a second gate structure located on the first gate structure and including second conductive layers and second insulating layers that are alternately stacked;
a source structure located on the second gate structure;
a bonding structure located between the peripheral circuit and the first gate structure and electrically connecting the peripheral circuit and the first gate structure to each other; and
a channel structure including a first portion extending through the first gate structure and a second portion extending through the second gate structure,
wherein a width difference between an uppermost surface and a lowermost surface of the first portion is greater than a width difference between an uppermost surface and a lowermost surface of the second portion.

22. The semiconductor device of claim 21, wherein the first portion has an inverted tapered shape, and the second portion has a less tapered shape than the first portion.

23. The semiconductor device of claim 21, wherein the uppermost surface of the first portion and the lowermost surface of the second portion are in contact with each other, and at a contact surface, the second portion has a greater width than the first portion.

24. The semiconductor device of claim 21, wherein the second portion includes a lower portion having an inverted tapered shape and an upper portion having a tapered shape.

25. The semiconductor device of claim 21, wherein the source structure includes a plate portion located on the gate structure and a protrusion portion protruding into the gate structure and located to correspond to the channel structure.
